(19) United States
(12) Patent Application Publication
(10) Pub. No.: US 2026/0226623 A1
(43) Pub. Date: Aug. 6, 2026

(54) GAS FLOW ADJUSTMENT DEVICE FOR FURNACE TUBE APPARATUS AND FURNACE TUBE APPARATUS

(71) Applicant: SWAYSURE TECHNOLOGY CO., LTD., Shenzhen (CN)

(72) Inventor: Rui ZHANG, Shenzhen (CN)

(21) Appl. No.: 19/444,778

(22) Filed: Jan. 9, 2026

(30) Foreign Application Priority Data
Jan. 17, 2025 (CN) CN 202510088924X

(51) Int. Cl. C23C 16/455; C23C 16/458; C23C 16/46

(52) U.S. Cl. CPC C23C 16/45589; C23C 16/4585; C23C 16/46

(57) ABSTRACT

The present disclosure relates to a gas flow adjustment device for a furnace tube apparatus and a furnace tube apparatus. The furnace tube apparatus comprises a wafer boat for carrying wafers. The gas flow adjustment device comprises: a plurality of gas flow adjustment rings, wherein central cavities of the plurality of gas flow adjustment rings form a receiving chamber for accommodating the wafer boat; a plurality of gas flow adjustment ring support rods configured to support the plurality of gas flow adjustment rings; and a lifting mechanism connected to the gas flow adjustment ring support rods for raising or lowering the gas flow adjustment ring support rods to vertically adjust the position of the gas flow adjustment rings, thereby adjusting gas flows flowing to the wafers on the wafer boat. The present disclosure provides the effect of improving the thickness uniformity of the film layer on the wafer surface.

### CROSS-REFERENCE TO RELATED APPLICATION

This application claims priority to Chinese Patent Application No. 202510088924X, filed on Jan. 17, 2025, which is incorporated herein by reference in its entirety and for all purposes.

### TECHNICAL FIELD

The present disclosure relates to the technical field of semiconductor processing, and specifically to a gas flow adjustment device for a furnace tube apparatus and a furnace tube apparatus.

### BACKGROUND

At present, it is generally necessary to deposit different types of films on the wafer surface in semiconductor manufacturing processes. In the related art, when a film is deposited using a furnace tube apparatus, the deposition thickness of the film in the edge region of a wafer is greater than that in the central region of the same wafer, resulting in poor thickness uniformity of the film layer across the wafer, which cannot be effectively improved by merely adjusting the parameters of the furnace tube apparatus.

### SUMMARY

A series of simplified concepts is introduced into the portion of Summary, which would be further illustrated in the portion of the detailed description. The Summary of the present disclosure does not mean attempting to define the key feature and essential technical feature of the claimed technical solution, let alone determining the protection scope thereof.

To address the existing problems, according to one aspect of the present disclosure, a gas flow adjustment device for a furnace tube apparatus is provided. The furnace tube apparatus comprises a wafer boat for carrying wafers, wherein the gas flow adjustment device comprises: a plurality of gas flow adjustment rings being in the shape of a circular ring sheet; a plurality of gas flow adjustment ring support rods extending in a first direction and spaced apart along outer peripheries of the gas flow adjustment rings, a distance between at least one pair of adjacent gas flow adjustment ring support rods of the plurality of gas flow adjustment ring support rods being greater than a radial dimension of the wafers carried on the wafer boat, and the plurality of gas flow adjustment ring support rods being configured to support the plurality of gas flow adjustment rings, wherein the plurality of gas flow adjustment rings are arranged at intervals in the first direction, and central cavities of the plurality of gas flow adjustment rings form a receiving chamber for accommodating the wafer boat; and a lifting mechanism connected to the gas flow adjustment ring support rods for raising or lowering the gas flow adjustment ring support rods to adjust a position of the gas flow adjustment rings, thereby adjusting gas flows flowing to the wafers on the wafer boat.

According to another aspect of the present disclosure, a furnace tube apparatus is provided, comprising the gas flow adjustment device and a wafer boat for carrying wafers.

### BRIEF DESCRIPTION OF THE DRAWINGS

The following drawings are hereby incorporated as part of the present disclosure for the understanding of the present disclosure. The embodiments of the present disclosure are illustrated and described in the drawings in order to explain the principles of the present disclosure.

In the drawings:

FIG. 1 shows a schematic view of a gas flow adjustment device according to an embodiment of the present disclosure.

FIG. 2 shows a schematic view of a wafer boat according to an embodiment of the present disclosure.

FIG. 3 shows a schematic view of the gas flow adjustment device in assembly with the wafer boat according to an embodiment of the present disclosure.

FIG. 4 shows a top view of the gas flow adjustment device in assembly with the wafer boat according to an embodiment of the present disclosure.

FIG. 5A and FIG. 5B show schematic views of gas flow changes according to an embodiment of the present disclosure.

FIG. 6A and FIG. 6B show the wafer film layer thickness vs. position profiles for the related art and in the present disclosure.

### REFERENCE NUMBERALS

100. Gas flow adjustment device; 110. Gas flow adjustment ring; 120. Gas flow adjustment ring support rod; 130. Motor; 140. Lead screw; 150. Lifting bracket; 160. Stage; 170. Receiving chamber; 200. Wafer Boat; 210. Wafer support rod; 220. Base; 230. Upper cover plate; 240. Lower cover plate; 300. Wafer.

### DETAILED DESCRIPTION

In the following description, numerous specific details are set forth in order to provide a more thorough understanding of the present disclosure. However, it is obvious to those skilled in this art that the present disclosure may be implemented without one or more of these details. Some technical features well-known in this art are not described in other examples in order to avoid confusion with the present disclosure.

It is to be understood that the present disclosure can be implemented in various forms but should not be construed as being limited to the embodiments set forth herein. On the contrary, these embodiments are provided to make the disclosure thorough and complete and the scope of the present disclosure be completely conveyed to those skilled in the art. In the drawings, the sizes and relative sizes of layers and regions may be exaggerated for clarity. The same reference numerals throughout represent the same elements.

It should be understood that when an element or layer is referred to as “on . . . ”, “adjacent to . . . ”, “connected to” or “coupled to” other elements or layers, it can be directly on, adjacent to, connected to or coupled to other elements or layers, or there can be intermediate elements or layers. On the contrary, when an element is referred to as “directly on . . . ”, “directly adjacent to . . . ”, “directly connected to” or “directly coupled to” other elements or layers, there are no intermediate elements or layers. It will be understood that, although the terms first, second, third, etc. may be used to describe various elements, components, regions, layers and/or parts, these elements, components, regions, layers and/or parts should not be limited by these terms. These terms are only used to distinguish one element, component, region, layer or part from another element, component, region, layer or part. Therefore, without departing from the teachings of the present disclosure, the first element, component, region, layer or part discussed below could be represented as a second element, component, region, layer or part.

Spatial relationship terms such as “under”, “beneath”, “below”, “down”, “on”, “above”, etc., may be used herein to describe the relationships between one element or feature and another element(s) or feature(s) shown in the figures. It should be understood that the spatial relationship terms are intended to encompass different orientations of the device in use and operation in addition to the orientation shown in the figures. For example, if the device in the figures is flipped, then the elements or features described as “under other elements” or “under” or “below” will be oriented as “on” the other elements or features. Therefore, the exemplary terms “under” and “below” may include both upper and lower orientations. The device may be oriented otherwise (rotated 90 degrees or other orientations) and the spatial descriptors used herein are interpreted accordingly.

The terminology used herein is for the purpose of describing particular embodiments only and is not intended to limit the present disclosure. When they are used herein, the singular forms “a,” “an,” and “the” are intended to include the plural forms as well, unless the context clearly indicates otherwise. It should also be understood that the terms “comprising” and/or “including”, when used in this specification, specify the presence of the features, integers, steps, operations, elements and/or components but not to exclude the presence or addition of one or more other features, integers, steps, operations, elements, components and/or groups. When they are used herein, the terms “and/or” include any or all combinations of related listed items.

In order to understand the present disclosure thoroughly, a detailed structure is provided in the following descriptions so as to elucidate the technical solutions presented in the present disclosure. Better embodiments of the present disclosure are illustrated in detail as below. However, the present disclosure may further have other embodiments in addition to these detailed descriptions.

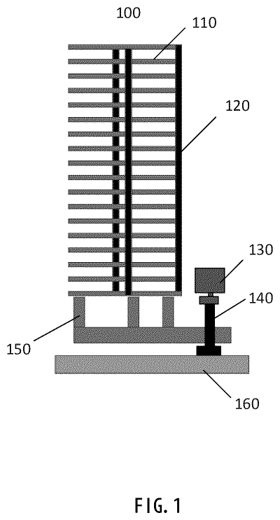

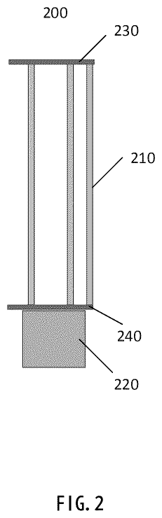

As shown in FIGS. 1-2, an embodiment of the present disclosure provides a gas flow adjustment device for a furnace tube apparatus. The furnace tube apparatus includes a wafer boat 200 for carrying wafers. The gas flow adjustment device 100 includes a plurality of gas flow adjustment rings 110, a plurality of gas flow adjustment ring support rods 120, and a lifting mechanism.

Wherein, each of the gas flow adjustment rings 110 is in the shape of a circular ring sheet. The plurality of gas flow adjustment ring support rods 120 extend in a first direction and are spaced apart along the outer peripheries of the gas flow adjustment rings 110. The distance between at least one pair of adjacent gas flow adjustment ring support rods 120 of the plurality of gas flow adjustment ring support rods 120 is greater than a radial dimension of the wafers on the wafer boat 200, so as to facilitate the loading or unloading of the wafers. The plurality of gas flow adjustment ring support rods 120 are configured to support the plurality of gas flow adjustment rings 110, wherein the plurality of gas flow adjustment rings 110 are arranged at intervals in the first direction, and the central cavities of the plurality of gas flow adjustment rings 110 form a receiving chamber for accommodating the wafer boat 200. The lifting mechanism is connected to the gas flow adjustment ring support rods 120, and is configured to raise or lower the gas flow adjustment ring support rods 120 to vertically adjust the position of the gas flow adjustment rings 110, thereby adjusting the distribution of the gas flow flowing to the wafers within the wafer boat 200.

The gas flow adjustment device in the embodiment of the present disclosure can drive the gas flow adjustment ring support rods 120 via the lifting mechanism. When the gas flow adjustment ring support rods 120 are driven, the gas flow adjustment rings 110 can be raised or lowered. The central cavities of the gas flow adjustment rings 110 form a receiving chamber for accommodating the wafer boat 200. The wafer boat 200 is configured to carry the wafers. By adjusting the position of the gas flow adjustment rings 110, the distribution of the gas flow passing through the wafers can be adjusted to make the distribution of the gas flow more uniform. Moreover, the gas flow adjustment rings 110 can also adjust the thermal radiation field at the edge of any wafer, thereby improving the uniformity of the thickness of the film layer formed on the wafer.

Exemplarily, the first direction in the embodiment of the present disclosure is vertical direction. The wafer boat 200 includes an upper cover plate 230, a lower cover plate 240, and a plurality of wafer support rods 210. The upper cover plate 230 and the lower cover plate 240 are connected via the plurality of wafer support rods 210. Each of the wafer support rods 210 is respectively provided with a plurality of evenly spaced grooves along the first direction for receiving and supporting the wafers such that the wafers are carried at intervals along the first direction in the wafer boat 200. The plurality of gas flow adjustment rings 110 correspond one-to-one with the grooves on each of the wafer support rods 210. Through the structure of the upper cover plate 230 and the lower cover plate 240, two ends of the wafer boat can be sealed, and gas flow passing through the sides of the wafer boat can be reduced. Optionally, each wafer support rod 210 may have an identical number of grooves, with one-to-one correspondence between them.

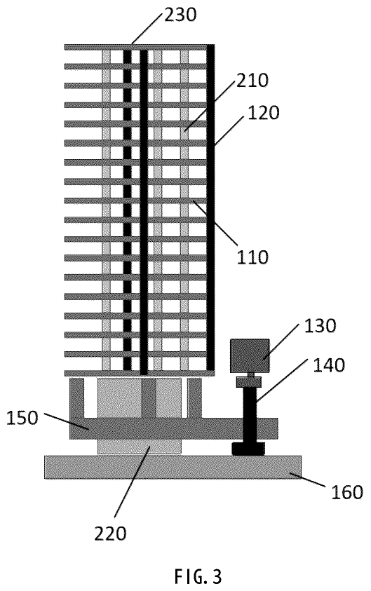

Referring to FIG. 3, the lifting mechanism in the embodiment of the present disclosure is described below. The lifting mechanism includes a lifting bracket 150 and a driving mechanism. The lifting bracket 150 is connected to the plurality of gas flow adjustment ring support rods 120, and the driving mechanism is connected to the lifting bracket 150. The driving mechanism is configured to drive the lifting bracket 150 to move up and down, thereby raising or lowering the gas flow adjustment ring support rods 120.

Exemplarily, the lifting mechanism is configured to, when loading or unloading a wafer, vertically adjust the position of the gas flow adjustment ring support rods 120 to move the gas flow adjustment rings 110 to a first position, such that the upper surface of each of the gas flow adjustment rings 110 is flush with the lower surface of a corresponding groove on the same layer. When processing the wafer, the position of the gas flow adjustment ring support rods 120 is vertically adjusted to move the gas flow adjustment rings 110 to a second position, such that the upper surface of each of the gas flow adjustment rings 110 is flush with or higher than the upper surface of a corresponding wafer on the same layer.

Specifically, when loading or unloading the wafer, the gas flow adjustment ring support rods 120 are raised or lowered to move the gas flow adjustment rings 110 to the first position. When the gas flow adjustment rings 110 are located at the first position, the upper surface of each gas flow adjustment ring 110 is flush with the lower surface of a corresponding groove, such that the space between the gas flow adjustment rings 110 allows wafers to be loaded or unloaded. That is, by controlling the gas flow adjustment rings 110 to move to the first position via the lifting mechanism, the gas flow adjustment rings 110 are offset from the grooves on the wafer boat 200, thereby facilitating the loading or unloading of the wafers into or from the wafer boat 200. Exemplarily, the wafers are loaded into or unloaded from the wafer boat 200 by horizontal movement. During processing, the gas flow adjustment rings 110 are moved to the second position such that the upper surface of each gas flow adjustment ring 110 can either be flush with the upper surface of a wafer to cause the distribution of the gas flow over the wafer to be more uniform after the adjustment, or be higher than the upper surface of the wafer. As such, the purpose of adjusting the direction of the gas flow can be achieved, and different process requirements can be met.

Exemplarily, the driving mechanism includes a lead screw 140 and a motor 130. The lead screw 140 is threadedly connected to the lifting bracket 150 and is arranged vertically. The motor 130 is connected to the lead screw 140 with the output shaft of the motor 130 connected to the lead screw 140. When the motor 130 operates, it drives the lead screw 140 to rotate. The lifting bracket 150 is in threaded engagement with the lead screw 140, which allows the lifting bracket 150 to move up and down along the lead screw 140 in the vertical direction when the lead screw 140 rotates, thereby enabling the driving of the lifting bracket and the gas flow adjustment ring support rods 120. As the gas flow adjustment ring support rods 120 moves up and down, the gas flow adjustment rings 110 are driven to move up and down, thus enabling the raising or lowering of the gas flow adjustment rings 110 to change the relative position of the gas flow adjustment rings 110 with respect to the wafer boat 200. It is worth mentioning that the driving mechanism in the embodiment of the present disclosure is only shown as an example, and other suitable driving mechanisms may also be applied to the present disclosure.

Exemplarily, the bottom of the wafer boat 200 is provided with a base 220. In an embodiment, the base 220 is connected with the lower cover plate 240 of the wafer boat 200. The base 220 can be movably arranged within the lifting bracket 150. When the lead screw 140 rotates, the base 220 can guide the lifting bracket 150 so that the lead screw 140 can smoothly drive the lifting bracket 150 to raise or lower in the vertical direction. In some embodiments, the base 220 extends through the lifting bracket 150. More specifically, a receiving space for accommodating the base 220 is formed in the middle of the lifting bracket 150, and the lifting bracket 150 is sleeved over the outside of the base 220, thereby providing a movable connection between the base 220 and the lifting bracket 150. The structure of the base 220 can be configured to guide the raising or lowering of the lifting bracket 150.

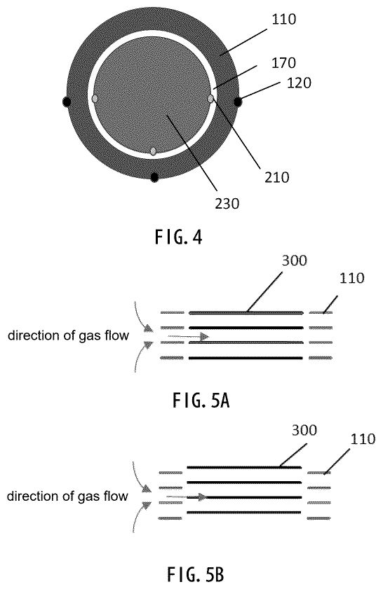

The working process of the gas flow adjustment device will be described below with reference to FIGS. 3-4. The receiving chamber 170 of the gas flow adjustment device is configured to accommodate the wafer boat 200, and each gas flow adjustment ring 110 may correspond to a wafer in the wafer boat 200. The lifting mechanism in the embodiment of the present disclosure is also configured to adjust the position of the gas flow adjustment rings 110 so as to facilitate the loading and unloading of the wafer in the wafer boat 200. For example, when loading or unloading the wafer, the lifting mechanism adjusts the position of the gas flow adjustment ring support rods 120 to move the gas flow adjustment rings 110 to the first position, such that the upper surface of each gas flow adjustment ring 110 is flush with the lower surface of a corresponding groove on the same layer. The gas flow adjustment device in the present disclosure is applied to a furnace tube apparatus, which includes a stage 160. The driving mechanism and the gas flow adjustment device 100 are arranged on the stage 160. The base 220 at the bottom of the wafer boat 200 is positioned on the stage 160. The stage 160 can provide support for the structures of the gas flow adjustment device 100 and the wafer boat 200. The furnace tube apparatus holds the wafers with the wafer boat 200. The wafers are received and supported in the grooves of the wafer boat 200. The furnace tube apparatus is used to grow a film layer on the wafers held in the wafer boat 200.

During wafer processing, the distribution of the gas flow passing through the wafers can be adjusted by controlling the raising and lowering of the gas flow adjustment rings 110 via the lifting mechanism. For example, by raising or lowering the position of the gas flow adjustment ring support rods 120 via the lifting mechanism, the gas flow adjustment rings 110 can be moved to the second position such that the upper surface of each gas flow adjustment ring 110 is flush with or higher than the upper surface of a corresponding wafer on the same layer, to adjust the distribution of the gas flow passing through the wafer, thereby making the distribution of the gas flow more uniform. Moreover, the gas flow adjustment rings 110 can also adjust the thermal radiation field at the edge of the wafer, thereby improving the uniformity of the thickness of the film layer formed on the wafer.

Exemplarily, the wafer boat 200 is configured to be detachably disposed inside the gas flow adjustment device 100. By raising or lowering the gas flow adjustment device 100, the relative position of the wafer boat 200 with respect to the gas flow adjustment device 100 can be changed.

By driving the gas flow adjustment rings 110 to be offset from the grooves on the wafer boat 200 via the lifting mechanism, the wafers to be processed can be loaded into the grooves of the wafer boat, thus achieving the loading of the wafers. Similarly, the wafers can also be unloaded. After the wafers are loaded into the grooves, the wafer boat 200 and the gas flow adjustment device 100 can be placed inside the furnace tube apparatus to form a film layer on the wafers. The gas flow flows through the sides of the gas flow adjustment rings 110 into the wafer boat 200 and contacts the wafers. The gas flow adjustment rings 110 can be adjusted with the lifting mechanism. When the position of the gas flow adjustment rings 110 in the vertical direction changes, each gas flow adjustment ring 110 becomes offset relative to the corresponding groove and the wafer received in the groove, causing the direction of the gas flow being changed. This ensures that the gas flow would no longer contact the wafers from only a fixed direction, yielding a more uniform gas flow distribution and improved thickness uniformity of the film layer on the wafers.

As shown in FIGS. 5A-5B, when the position of the gas flow adjustment rings 110 is in correspondence with the grooves, for example, the gas flow adjustment rings 110 are located at the second position such that the upper surface of each gas flow adjustment ring 110 is flush with the upper surface of the corresponding wafer on the same layer, the coverage area of the gas flow is stretched radially. As a result, after the gas flow first enters at high speed from the gas flow adjustment rings 110 at the edge, the gas flow rate tends to be gentle, thereby making the pressure difference or gas flow rate difference of the gas corresponding to an entire wafer smaller, yielding a more uniform gas flow distribution for each wafer and improved thickness uniformity of the film deposited on the wafers. After the position of the gas flow adjustment rings 110 has been adjusted, for example, to ensure the upper surface of each gas flow adjustment ring 110 to be higher than that of a corresponding wafer on the same layer, the gas flow adjustment rings 110 and the grooves become misaligned in the vertical direction. As such, when the gas flow passes through the gas flow adjustment rings 110, the position at which the gas flow contacts the wafer will also be changed. The gas flow will become closer to the wafer below, thus the gas flow distribution at the edge of the wafer will be adjusted to more closely match that in the central area of the wafer. As a result, the uniformity of the gas flow distribution is improved.

Exemplarily, the inner diameter of the gas flow adjustment ring 110 ranges from 304 mm to 350 mm, and the outer diameter of the gas flow adjustment ring 110 ranges from 410 mm to 550 mm. The inner diameter range of the gas flow adjustment ring 110 and the outer diameter range of the wafer boat 200 are adapted to each other, and a certain gap is left between the inner side of the gas flow adjustment ring 110 and the outer side of the wafer boat 200. The gas flow adjustment ring 110 has a certain width in the radial direction (i.e., half the difference between its inner and outer diameters), so that the gas flow has a suitable stroke when passing through the gas flow adjustment ring 110 and can effectively adjust the flow direction of the gas flow. Exemplarily, the gap between the inner wall of the gas flow adjustment ring 110 and the outer side of the wafer boat 200 ranges from 2 mm to 25 mm. It is worth mentioning that the above numerical ranges are only examples, and other suitable values may also be adapted to the present disclosure.

In order to adjust the thermal radiation field at the edge of each wafer and make the thickness of the film deposited on the wafers more uniform, exemplarily, the specific heat capacity of the material of the gas flow adjustment ring 110 is different from that of the film layer. Due to the difference in specific heat capacity, the gas flow adjustment ring 110 and the film layer will experience different temperature rises and falls, thereby adjusting the thermal radiation field of the outer circle of the wafer. In one specific example, to address the issue that the film layer in the edge region of the wafer is thicker than that in the central region of the wafer, the material of the gas flow adjustment ring 110 has a specific heat capacity less than that of the film layer. Since the gas flow adjustment ring 110 has a smaller specific heat capacity, it can change its own temperature more quickly with changes in ambient temperature (such as gas flow temperature), thereby reducing the thermal radiation in the edge region of the wafer, further lowering the growth rate of the film in the edge region, reducing the thickness of the film layer deposition, and improving the uniformity of the film layer. Optionally, the material of the gas flow adjustment ring 110 comprises at least one of silicon, quartz, or silicon carbide. During manufacturing and use, the material of the gas flow adjustment ring 110 can be selected according to actual conditions, on which the embodiments of the present disclosure do not make limitations.

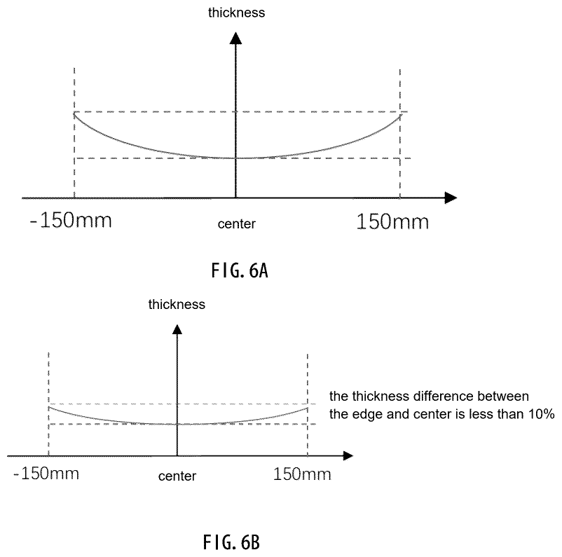

Refer to FIGS. 6A and 6B, which respectively show the film layer thickness vs. position profiles for the related art and the present disclosure. The origin in the figures represents the center of a wafer, the horizontal axis represents the distance from the wafer center, and the vertical axis represents the thickness of the film layer. By comparison, it can be seen that in the related art, the thickness of the edge region of the film layer is significantly greater than that of the center region, and the difference can be up to 40%. By contrast, in the present disclosure, the thickness difference between the edge region and center region of the film layer is even smaller, and the difference is less than 10%. This indicates that the present disclosure can effectively address the issue of non-uniform thickness of the film layer.

The embodiment of the present disclosure further provides a furnace tube apparatus comprising a gas flow adjustment device as discussed above and a wafer boat for carrying wafers. The wafer boat 200 is used to hold the wafers for forming a film layer on the wafers. The gas flow adjustment device 100 is used to change the direction of the gas flow to ensure the uniformity of the film layer on the wafers and to adapt to the needs of different manufacturing processes. Optionally, the furnace tube apparatus can be a low-pressure chemical vapor deposition device, a high-temperature furnace tube oxidation device, or any other suitable film deposition apparatus.

The furnace tube apparatus in the embodiment of the present disclosure can drive the gas flow adjustment ring support rods 120 via the lifting mechanism. When the gas flow adjustment ring support rods 120 are driven, the gas flow adjustment rings 110 can be raised or lowered. The central cavities of the gas flow adjustment rings 110 form a receiving chamber for accommodating the wafer boat 200. The wafer boat 200 is used to carry the wafers. By adjusting the position of the gas flow adjustment rings 110, the distribution of the gas flow passing through the wafers can be adjusted so as to regulate the thermal radiation field of the outer circle of the wafer and ensure the thickness uniformity of the film layer formed on the wafer.

Although the above example embodiments have been described with reference to the drawings, it is to be understood that the above-described example embodiments are for illustrative purposes only and are not intended to limit the scope of the present disclosure thereto. Those of ordinary skill in the art can make various variations and modifications therein but not deviate from the scope and spirit of the present disclosure. All these variations and modifications are intended to be included within the scope of the present disclosure as claimed by the claims attached.

Similarly, it is to be understood that respective features of the present disclosure are sometimes grouped together to the single embodiment, the drawing, or the depiction thereof in the description of the exemplary embodiments of the present disclosure, in order to simplify the present disclosure and facilitate understanding of one or more aspects of the disclosure. However, the method of the present disclosure shall not be explained to reflect the following intention, that is, the claimed present disclosure claims more features than those explicitly recited in each claim. To be more accurate, as reflected by the corresponding claims, the inventive ideas thereof lie in that the corresponding technical problem may be resolved with the feature fewer than all features of the single embodiment of some disclosure. Thus, the claims complying with the embodiments are hereby explicitly incorporated into the embodiments, wherein each claim itself serves as an independent embodiment of the present disclosure.

In addition, it would be understood by those skilled in the art that although some embodiments described herein comprise some features that are included in other embodiments but not other features, the combination of the features of different embodiments means falling into the scope of the present disclosure and forming different embodiments. For example, in the claims, any one of the claimed embodiments may be used in a manner of an arbitrary combination.

It should be noted that the abovementioned embodiments illuminate the present disclosure and do not pose a limitation on the present disclosure. Moreover, those skilled in the art may design alternative embodiments without separating from the scope of the claims attached. In the claims, any reference symbols between parentheses shall not be configured as limitation on the claims. The use of the words “first”, “second” and “third” does not indicate any order, and these words may be construed as names.

What is claimed is:

1. A gas flow adjustment device for a furnace tube apparatus comprising a wafer boat for carrying wafers, wherein the gas flow adjustment device comprises:
a plurality of gas flow adjustment rings being in the shape of a circular ring sheet;
a plurality of gas flow adjustment ring support rods extending in a first direction and spaced apart along outer peripheries of the gas flow adjustment rings, a distance between at least one pair of adjacent gas flow adjustment ring support rods of the plurality of gas flow adjustment ring support rods being greater than a radial dimension of the wafers carried on the wafer boat, and the plurality of gas flow adjustment ring support rods being configured to support the plurality of gas flow adjustment rings, wherein the plurality of gas flow adjustment rings are arranged at intervals in the first direction, and central cavities of the plurality of gas flow adjustment rings form a receiving chamber for accommodating the wafer boat;
a lifting mechanism connected to the gas flow adjustment ring support rods for raising or lowering the gas flow adjustment ring support rods to vertically adjust the position of the gas flow adjustment rings, thereby adjusting gas flows flowing to the wafers on the wafer boat.

2. The gas flow adjustment device of claim 1, wherein the wafer boat comprises an upper cover plate, a lower cover plate, and a plurality of wafer support rods, the upper cover plate and the lower cover plate are connected via the plurality of wafer support rods, each of the wafer support rods is respectively provided with a plurality of evenly spaced grooves along the f irst direction for receiving and supporting the wafers such that the wafers are carried at intervals in the wafer boat along the first direction, and the plurality of gas flow adjustment rings correspond one-to-one with the grooves on each of the wafer support rods.

3. The gas flow adjustment device of claim 2, wherein the lifting mechanism is configured to:
when loading or unloading a wafer, vertically adjust the position of the gas flow adjustment ring support rods to move the gas flow adjustment rings to a first position, such that the upper surface of each of the gas flow adjustment rings is flush with the lower surface of a corresponding groove on the same layer;
when processing a wafer, vertically adjust the position of the gas flow adjustment ring support rods to move the gas flow adjustment rings to a second position, such that the upper surface of each of the gas flow adjustment rings is flush with or higher than the upper surface of a corresponding wafer on the same layer.

4. The gas flow adjustment device of claim 1, wherein the lifting mechanism comprises:
a lifting bracket connected to the plurality of gas flow adjustment ring support rods;
a driving mechanism connected to the lifting bracket and configured to drive the lifting bracket to move up and down, thereby raising or lowering the gas flow adjustment ring support rods.

5. The gas flow adjustment device of claim 4, wherein the driving mechanism comprises:
a lead screw threadedly connected to the lifting bracket and arranged vertically;
a motor connected to the lead screw and configured to drive the lead screw to rotate such that the lifting bracket moves up and down along the lead screw.

6. The gas flow adjustment device of claim 4, wherein the furnace tube apparatus comprises a stage on which the driving mechanism and the gas flow adjustment device are disposed, and the wafer boat has a base that extends through the lifting bracket and is positioned on the stage.

7. The gas flow adjustment device of claim 1, wherein the furnace tube device is configured to grow a film layer on the wafers held in the wafer boat, and wherein specific heat capacity of the material of the gas flow adjustment ring is different from that of the film layer.

8. The gas flow adjustment device of claim 7, wherein the specific heat capacity of the material of the gas flow adjustment ring is less than that of the film layer.

9. The gas flow adjustment device of claim 7, wherein the material of the gas flow adjustment ring comprises at least one of: silicon, quartz, or silicon carbide.

10. The gas flow adjustment device of claim 1, wherein an inner diameter of the gas flow adjustment ring ranges from 304 mm to 350 mm, an outer diameter of the gas flow adjustment ring ranges from 410 mm to 550 mm, and a gap between an inner wall of the gas flow adjustment ring and the wafer boat ranges from 2 mm to 25 mm.

11. A furnace tube device, comprising the gas flow adjustment device of claim 1 and a wafer boat for carrying wafers.

12. A furnace tube device, comprising the gas flow adjustment device of claim 2 and a wafer boat for carrying wafers.

13. A furnace tube device, comprising the gas flow adjustment device of claim 3 and a wafer boat for carrying wafers.

14. A furnace tube device, comprising the gas flow adjustment device of claim 4 and a wafer boat for carrying wafers.

15. A furnace tube device, comprising the gas flow adjustment device of claim 5 and a wafer boat for carrying wafers.

16. A furnace tube device, comprising the gas flow adjustment device of claim 6 and a wafer boat for carrying wafers.

17. A furnace tube device, comprising the gas flow adjustment device of claim 7 and a wafer boat for carrying wafers.

18. A furnace tube device, comprising the gas flow adjustment device of claim 8 and a wafer boat for carrying wafers.

19. A furnace tube device, comprising the gas flow adjustment device of claim 9 and a wafer boat for carrying wafers.

20. A furnace tube device, comprising the gas flow adjustment device of claim 10 and a wafer boat for carrying wafers.
